(19) United States
(12) Patent Application Publication
(10) Pub. No.: US 2008/0303150 A1
(43) Pub. Date: Dec. 11, 2008

(54) High-Density Fine Line Structure And Method Of Manufacturing The Same

(76) Inventors: Chien-Wei Chang, Taoyuan (TW); Ting-Hao Lin, Taipei (TW)

Correspondence Address: LIN & ASSOCIATES INTELLECTUAL PROPERTY, INC., P.O. BOX 2339, SARATOGA, CA, 95070-0339, US

(21) Appl. No.: 11/760,079

(22) Filed: Jun. 8, 2007

(51) Int. Cl. H01L 23/488; H01L 21/60

(52) U.S. Cl. 257/738; 438/108; 257/E21.506; 257/E23.023

(57) ABSTRACT

A high-density fine line circuit structure mainly includes: a first semiconductor device, an insulated layer on the same surface, an outer circuit layer above the first semiconductor device, and a solder mask formed on the outer circuit layer. The surface which is not covered by the solder mask can be made to be a pad, and electrically connected with a second semiconductor device. The fine line circuit layer, which is exposed, is to be a tin ball pad where a tin ball is filled. Electroplating rather than the etching method is used for forming the fine line circuit layer, and a carrier and a metal barrier layer, which are needed during or at the end of the manufacturing process, are removed to increase the wiring density for realizing the object of high-density.

### BACKGROUND OF THE INVENTION

1. Field of the Invention

The present invention relates generally to a method of manufacturing a package structure, and in particular, to a high-density fine line structure and method of manufacturing the same.

2. The Prior Arts

One of the important challenges in the IC industry is how to keep under a proper cost for assembling various types of functions inside a limited package form done effectively, so that chips performing different functions are to reach optimal performance. However, in the applications as used in the digital, analog, memory, and wireless communications fields, etc, different electrical circuits having different functionalities can produce different performance requirements and results corresponding to under the production technology scaling. Therefore, a single chip having many integrated functions may not provide the most optimal solution. As the SOC, SiP, PiP (Package-in-Package), PoP (Package-on-Package), and stack CSP technique have rapidly advanced, it can be predicted that the most capable system chip is a packaged system which can make the most of the space allowance to integrate various chips having different functions under the various different technologies and different voltage operation environments.

In detail, the system-in-package (SIP) is a package in which chips of various IC types are assembled. A new technique which is developed from the SIP is to be able to stack many chips inside a package module, and to be able to provide or integrate more functions or higher density by utilizing the third dimensional space. In packaging structures, the stack CSP is firstly launched to the public, of which the corresponding products are memory combo, and is able to stack six layers of memory chips in a BGA package. Herein, apart from the conventional wire bonding, the solder bumps or the flip-chip technique can also be used, while the interposers can be added to assist stacking, or perhaps the heat extraction can also be gradually applied.

For example, a package of the stack chips should include the dies as the building blocks which are in separated-form each other, but are connected with each other by conducting wires, and may include the stack of one or more memory chips, an analog chip stacked on another SOC or digital chip, and also another separate RF chip disposed on a multi-layer interconnected substrate, where these chips have different control and I/O (input/output) paths. Moreover, if there is a memory in the stacked chip, the control software can write into the non-volatile memory (NVM).

However, because the conventional fine line technique is unable to achieve any major breakthrough in technology, the manufacturing process for fabricating the more complicated package structure as described above cannot yield greater further overall package volume reductions, for meeting the growing thinner and lighter requirements of the electronic devices.

In the conventional manufacturing of the 50 μm fine pitch line circuit on the build up material such as the glass-fiber-reinforced resin material, the method includes: using a 1.5˜5.0 μm thin copper as the conductive layer for the pattern plating, the flash etching is performed to etch the thin copper layer with thickness of 1.5˜5.0 μm. Because a rough surface of the thin copper layer is required to be combined with the glass-fiber-reinforced resin material, the rough surface structure of the thin copper layer is therefore required in the corresponding method. According to the structure, the etching operation as required is to lead to increased etching depth for processing, thereby resulting in the damage to the wire width after plating. Due to the thickness of the thin copper layer, the etching amount may not be reduced further, and therefore, high-density board having thinner fine pitch lower than 50 μm can not be manufactured.

During plating of the nickel on the fine line circuit layer of the printed circuit board, the electrical current is transmitted into the board, especially for the fine line circuit layer required to be electroplated, it is necessary that the electrical current may be transmitted by the conductor trace lines which are connected with the fine line circuit layer. Although the fine line circuit layer can be fully covered using the plated nickel layer by this method, the conductor trace lines are still retained in the printed circuit board after the plating, and thereby to occupy the limited wiring density. In order to decrease the wiring density, because the width of the conductor trace line then becomes relatively narrowed, the thickness of the plated nickel layer may not be uniform; therefore, the decrease of the width of the conductor trace line may not be suitable for use for increasing the wiring density.

In order to improve electrical performance and reducing interference, and at the same time, to increase the wiring density, the printed circuit board currently are designed without the conductor trace lines, and the adhesion of the wire bonding region may be optimized by nickel plating the nickel, rather than by using the chemical nickel plating (or the chemical gold plating) whose reliability is not as good. Therefore, the wire bonding region made without conductor trace lines but using nickel plating method are typically manufactured by the GPP operation.

However, before performing the GPP operation, because the plated nickel layer is formed before the solder mask (SM), the area of the plated nickel layer occupied under the SM is relatively large. Because the adhesion between the SM and the plated nickel layer is poor, the relatively high requirement for reliability and thermal stability today is unable to be met by the conventional manufacturing methods.

Otherwise, in the manufacturing method as in the non-plating line (NPL) method, besides having a complex set of procedures, a specialized machine is required for use for plating the thin copper layer, and the etching parameters for the etching are difficult for control after plating the thin copper; as a result, micro short are often resulted, or the micro short occurring during reliability testing are produced resulting in unmanageable situations.

No matter whichever type of NPL manufacturing method is used, the fine line layer is to be defined by the un-etched metal layer, and sometimes to rely on the selective etching of the metal layer. But, according to conventional method, the etching cannot be controlled accurately; therefore, the manufacturing of the fine line circuit cannot rely reliably upon etching, otherwise the fine pitch line circuit faces tremendous development barrier.

### SUMMARY OF THE INVENTION

A primary objective of the present invention is to provide a high-density fine line structure and method of manufacturing the same, which without using etching as the method for forming the circuit, only the patterned photoresist layer is used to define the location of the fine line layer, and the plating method is used to form the fine line layer (the plating electrical current is transmitted by a removable carrier or a metal barrier layer hereon.), and to form the fine line circuit for realizing the thinning effect. Later, the carrier and the metal barrier layer may be removed during or at the end of the manufacturing process to increase the wiring density for realizing the higher-density objective. Meanwhile, the higher-cost semi-additive process (SAP) technique is also not used in the present invention.

Based upon the above objective, the solution of the present invention is to provide a high-density fine line structure which includes a first semiconductor device, a fine line circuit layer, an insulated layer formed around the fine line circuit layer, an outer circuit layer formed above the first semiconductor device, and a solder mask layer formed on the outer circuit layer. The pad which is not be covered by the solder mask layer may be electrically connected with a second semiconductor device. The fine line circuit layer which is exposed can be as the solder ball pad for filling the solder balls.

### BRIEF DESCRIPTION OF THE DRAWINGS

The present invention will be apparent to those skilled in the art by reading the following detailed description of a preferred embodiment thereof, with reference to the attached drawings, in which:

FIG. 1A˜FIG. 1J are a plurality of cross-sectional views showing a manufacturing method of a high-density fine line structure in accordance with an embodiment of the present invention; and

FIG. 2 is a cross-sectional view showing a high-density fine line structure in accordance with another embodiment of the present invention.

### DETAILED DESCRIPTION OF THE PREFERRED EMBODIMENT

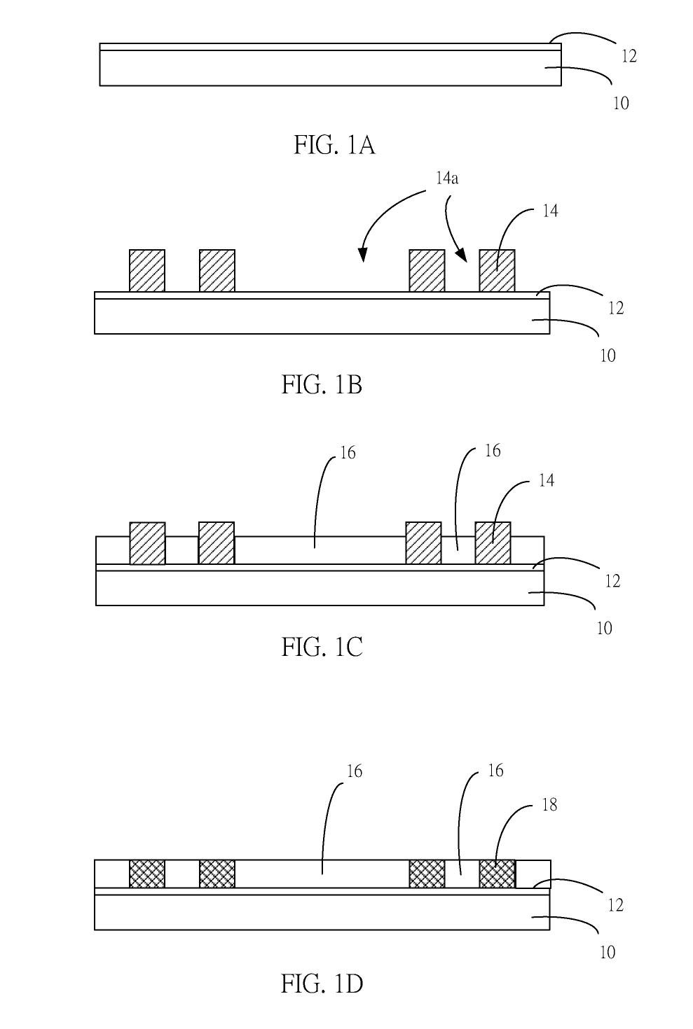

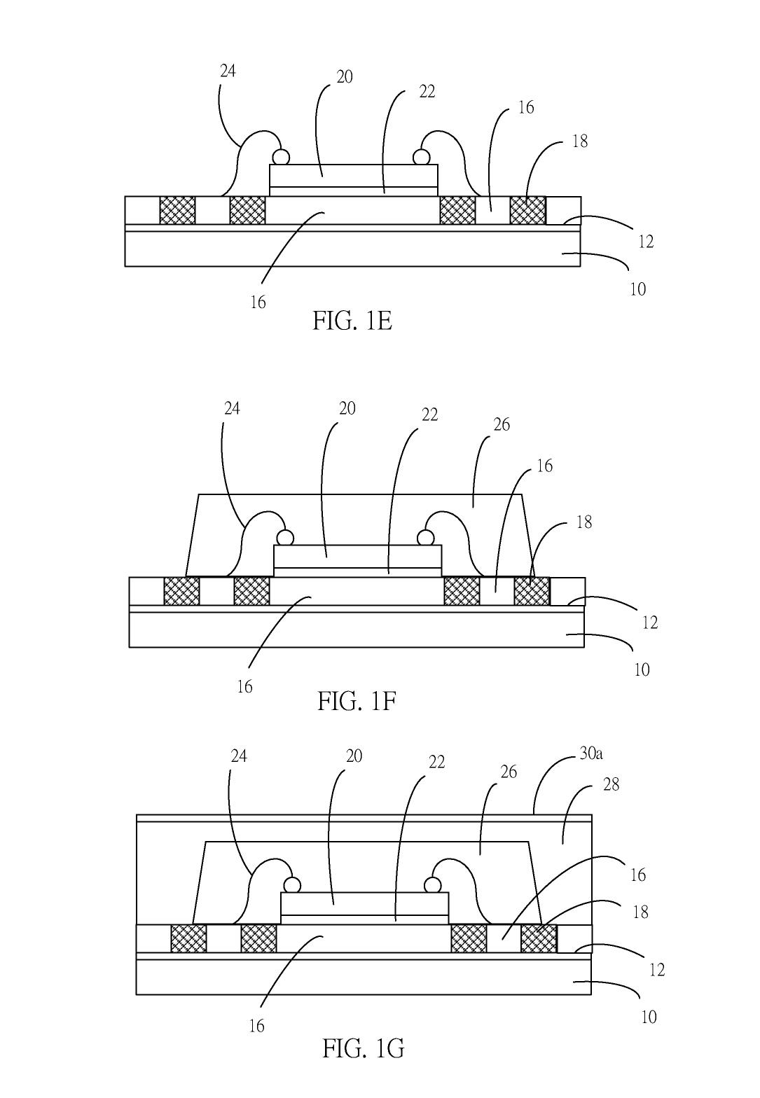

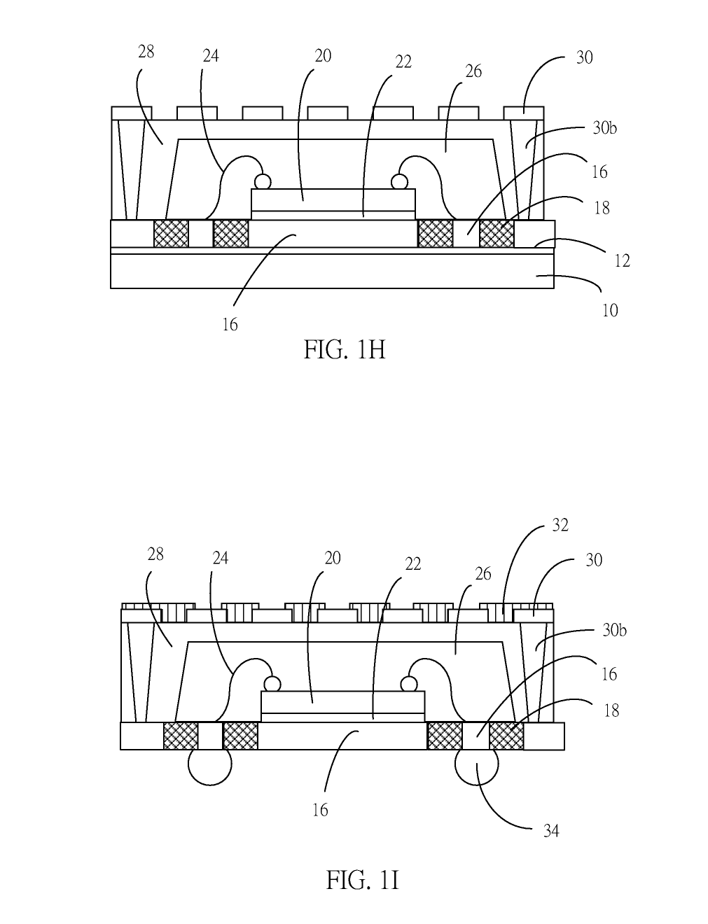

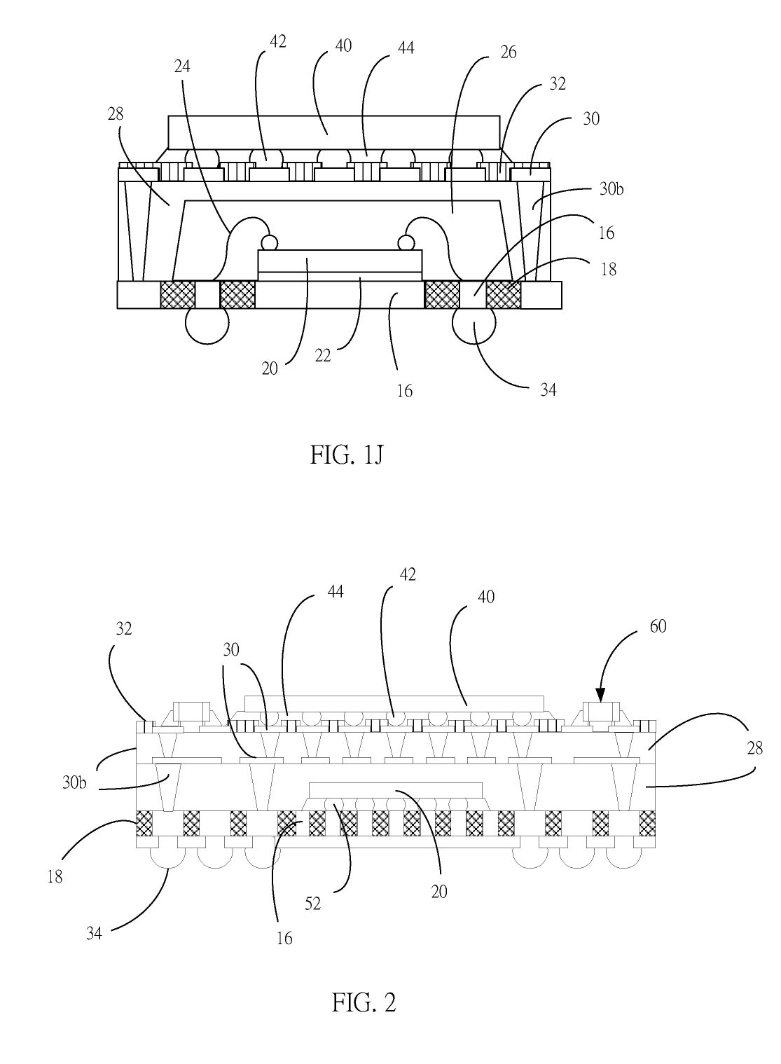

With reference to the drawings and in particular to FIG. 1A˜FIG. 1J, a manufacturing method of a high-density fine line structure provided in accordance with the present invention is shown, in which the part for forming the circuit without etching is shown in FIG. 1A˜FIG. 1D, and the completed 3D packaging structure is presented in FIG. 1E˜FIG. 1J.

Simply speaking, as shown in FIG. 1C, the high-density fine line structure and method of manufacturing the same provided in the present invention mainly includes: the metal barrier layer 12 (or the carrier 10 itself) by which the plating current can be transmitted so that the fine line circuit layer 16 may be formed without etching (which is only attainable through the capability of manufacturing finer detailed circuits.). The position of the fine line circuit 16 is defined by the patterned photoresist layer 14, and then the fine line circuit 16 is formed by the plating method, so as to improve the fabrication capability of the fine pitch for meeting the needs of the first semiconductor device 20 having many I/Os. In addition, as shown in FIG. 1I, the carrier 10 and the metal barrier layer 12 are removed at the end of the process for increasing the wiring density for realizing the high-density IC packaging objective as shown in FIG. 1E˜FIG. 1J or in FIG. 2. Meanwhile, the semi-additive process (SAP), which has higher cost associated, may not be required to be used in the present invention for manufacturing the fine line circuit.

As shown in FIG. 1A˜FIG. 1D, the metal barrier layer 12 is first formed on the carrier 10, in particular as shown in FIG. 1A. For forming the fine line circuit layer 16 as shown in FIG. 1B, the patterned photoresist layer 14 is formed above the metal barrier layer 12 (whose photoresist opening 14a is for forming the circuit). And as shown in FIG. 1C, plating current is transmitted through the metal barrier layer 12, and then the fine line circuit layer 16 may be formed on the metal barrier layer 12 in the photoresist opening 14a. Thus, the patterned photoresist layer 14 is removed.

After the formation of the fine line circuit layer 16, the insulated layer 18 may be filled adjacent to the fine line circuit layer 16 on the metal barrier layer 12, as show in FIG. 1D.

Before filling in the insulated layer 18, in order to improve the reliability of the adhesive between the fine line circuit layer 16 and the filled insulated layer 18, the surface of the fine line circuit 16 may be processed first to increase the surface area and the degree of roughness of the fine line circuit layer 16. The surface processing can be performed by roughening the surface of the fine line circuit 16 or by forming a plurality of copper micro-bumps (or nodules) on the surface. Whatever the method is used, the purpose is that the fine line circuit layer 16 can remain firmly adhered to the insulated layer 18 and other package components due to the increased contact surface area, after removing the carrier 10 and the metal barrier layer 12 which were used to support the fine line circuit layer 16.

As shown in FIG. 1E, the first semiconductor device 20 is formed on the fine line circuit layer 16. The device operation reliability is improved with the help of the first semiconductor device 20 to disperse the heat if a sufficient area is provided and the surface is processed properly.

During the mounting of the first semiconductor device 20 on the fine line circuit layer 16, the first semiconductor device 20 may be installed using wire bonding as shown in FIG. 1E˜FIG. 1F or the flip chip as shown in FIG. 2. When using the wiring bonding as shown in FIG. 1E, the first semiconductor device 20 may be adhered to the copper surface by using the heat conductive adhesive, and the conductor trace line 24 may be connected with the terminals of the first semiconductor device 20 on the predetermined fine line circuit layer 16 by using the wiring bonder machine. Then the first semiconductor device 20 and the conductor trace line 24 may be encapsulated by using an adhesive 26, as shown in FIG. 1F. When using the flip chip for mounting the first semiconductor device 20 as shown in FIG. 2, the tin balls 52 are electrically connected with the fine line circuit layer 16, and the tin balls 52 are filled using the adhesive 50.

As shown in FIG. 1H, above the first semiconductor device 20 and above the fine line circuit layer 16 which is not be covered by the first semiconductor device 20, an outer circuit layer 30 may be formed. Before this process, as shown in FIG. 1G, above the first semiconductor device 20 and above the fine line circuit layer 16 which is not be covered by the first semiconductor device 20, the dielectric layer 28 may be formed. In addition, above the fine line circuit layer 16, the via post 30b may be formed inside the dielectric layer 28, then a metal layer 30a may be formed on the dielectric layer 28 and the via post 30b, thus the metal layer 30a may be patternized to form the outer circuit layer 30, as shown in FIG. 1H. If the fine line circuit layer 16 and the outer circuit layer 30 may not have needs for conduction, the via post 30b is not needed to be formed.

As shown in FIG. 1I, the solder mask 32 is selectively formed on the outer circuit layer 30. The surface which is not covered by the solder mask 32 may be made as the pad for electrically connecting with the second semiconductor device 40 as shown in FIG. 1J. The second semiconductor device 40 can be electrically connected with the outer circuit layer 30 by using the tin balls 42, and the second semiconductor device 40 is to be filled with the adhesive 44.

Therefore, as shown in FIG. 1I, the carrier 10 and the metal barrier layer 12 may be removed to expose the fine line circuit layer 16. Parts of the fine line circuit layer 16 can be used as the tin ball pads, for filling in the tin ball 34, for ease to install on the other circuit boards.

As shown in FIG. 1J, the high-density fine line structure mainly includes: the first semiconductor device 20 installed on the fine line circuit layer 16, the insulated layer 18 formed surrounding the fine line circuit layer 16, the outer circuit layer 30 above the first semiconductor device 20, and the solder mask 32 formed on the outer circuit layer 30.

Specially, in this structure, the fine line circuit layer 16 may be a plurality of layers, or as shown in FIG. 2, there are two layers to form the outer fine line circuit layer 30; and at the furthest outer layer of the outer fine line circuit layer 30, besides the installation of the second semiconductor device 40 as shown in FIG. 2, the passive device 60 may also be installed.

Although the present invention has been described with reference to the preferred embodiment thereof, it is apparent to those skilled in the art that a variety of modifications and changes may be made without departing from the scope of the present invention which is intended to be defined by the appended claims.

What is claimed is:

1. A manufacturing method of high-density fine line structure, comprising:
forming a metal barrier layer on a carrier;
forming a patterned photoresist layer on the metal barrier layer, and the patterned photoresist layer having a photoresist opening;
transmitting a plating current through the metal barrier layer, and forming a fine line circuit layer on the metal barrier layer in the photoresist opening;
removing the patterned photoresist layer;
filling in an insulated layer on the metal barrier layer and at the side of the fine line circuit layer;
installing a first semiconductor device above the fine line circuit layer; and
forming an outer circuit layer above the fine line circuit layer which is not covered by the first semiconductor device, and above the first semiconductor device; and
removing the carrier and the metal barrier layer, and exposing the fine line circuit layer, and parts of the fine line circuit layer are able to be a tin ball pad, as is used for filling in a tin ball.

2. The method as claimed in claim 1, further comprising: selectively forming a solder mask on the outer circuit layer, and the other surface which is not covered by the solder mask is to be made into a pad.

3. The method as claimed in claim 2, wherein the pad, which is filled with the tin balls, is electrically connected with a second semiconductor device.

4. The method as claimed in claim 1, wherein, during installing the first semiconductor device on the fine line circuit layer, the first semiconductor device is processed by using wire bonding or flip chip.

5. The method as claimed in claim 1, wherein when forming the outer circuit layer on the first semiconductor device, further comprising:
forming a dielectric layer above the first semiconductor device and above the fine line circuit layer which is not covered by the first semiconductor device;
forming a via post above the fine line circuit layer inside the dielectric layer, and the via post is for conducting current transmitted between the fine line circuit layer and the outer circuit layer; and
forming a metal layer on the dielectric layer and the via post, and patternizing the metal layer to be the outer circuit layer.

6. A high-density fine line structure, comprising:
a fine line circuit layer;
an insulating layer, formed on the same surface as the fine line circuit layer;
a first semiconductor device, installed on the fine line circuit layer; and
an outer circuit layer, formed above the first semiconductor device, and above the fine line circuit layer which is not covered by the first semiconductor device, wherein, the fine line circuit layer, which is exposed, is a tin ball pad for filling in a tin ball.

7. The structure as claimed in claim 6, wherein having a dielectric layer between the outer circuit layer and the first semiconductor device.

8. The structure as claimed in claim 6, further comprising: a solder mask, selectively forming on the fine line circuit layer, and the other surface of the fine line circuit layer which is not covered by the solder mask is to be made into a pad.

9. The structure as claimed in claim 8, wherein, the pad, which is filled with the tin ball, is electrically connected with a second semiconductor device.

10. The structure as claimed in claim 6, wherein, the fine line circuit layer is formed of a plurality of layers.
